(19) United States
(12) Patent Application Publication
(10) Pub. No.: US 2022/0037058 A1
(43) Pub. Date: Feb. 3, 2022

(54) MANUFACTURING METHOD FOR GRAPHENE FILM AND DISPLAY PANEL

(71) Applicants: Beihai HKC Optoelectronics Technology Co., Ltd., Beihai (CN); HKC Corporation Limited, Shenzhen (CN)

(72) Inventors: Yuming Xia, Beihai (CN); En-Tsung Cho, Beihai (CN); Lidan Ye, Beihai (CN)

(21) Appl. No.: 17/383,381

(22) Filed: Jul. 22, 2021

(30) Foreign Application Priority Data
Jul. 29, 2020 (CN) 202010745867.5

(51) Int. Cl. H01B 13/00; H01L 27/12; H01B 1/04; H01B 1/08; H01B 5/14; C08K 3/04

(52) U.S. Cl. CPC H01B 13/0036; H01L 27/124; H01B 1/04; C08K 2201/001; H01B 5/14; C08K 3/042; H01B 1/08

(57) ABSTRACT

The present application discloses a manufacturing method for a graphene film, a manufacturing method for a graphene material and a display panel. The manufacturing method for the graphene film includes steps of: obtaining a graphene oxide dispersion; reducing the graphene oxide dispersion to a graphene material by an electrochemical deposition method; preparing the graphene material into the graphene film.

The present application claims priority to Chinese Patent Application No. 202010745867.5, filed Jul. 29, 2020, which is hereby incorporated by reference herein as if set forth in its entirety.

### TECHNICAL FIELD

The present application relates to the field of manufacturing conductive materials, particularly to a manufacturing method for a graphene film, a manufacturing method for a graphene material and a display panel.

### BACKGROUND

The statements herein merely provide background information related to the present application and do not necessarily constitute the conventional art.

Transparent conductive films are films that can conduct electricity and realize some specific electronic functions, and are widely used in electronic devices such as displays, touch screens and solar cells. As a transparent and conductive semiconductor material, Indium Tin Oxide. (ITO) has been widely used in the field of conductive films at present.

A graphene film is the most suitable material to replace the ITO as the graphene film is superior to the ITO material in transparency and conductivity, and has characteristics that the ITO does not have in the flexibility field. How to manufacture the graphene film and improve its performance has become a growing concern.

### SUMMARY

The purpose of the present application is to provide a manufacturing method for a graphene film, and a display panel to manufacture a conductive film with good performance.

The present application discloses a manufacturing method for a graphene film, including steps of:
obtaining a graphene oxide dispersion;
reducing the graphene oxide dispersion to a graphene material by an electrochemical deposition method; and
preparing the graphene material into the graphene film.

The present application further discloses a manufacturing method for a graphene material, including steps of
obtaining a graphene oxide dispersion; and
reducing the graphene oxide dispersion to the graphene material by an electrochemical deposition method.

The present application further discloses a display panel, including a transparent conductive layer which is a graphene film prepared by the manufacturing method for the graphene film.

According to the present application, graphene is prepared by reduction through an electrochemical deposition method, so that electrochemical parameters can be controlled as required in the reduction process, the particle size of the prepared graphene is small, the graphene film prepared from the graphene with small particle size has high density, and graphene particles are tightly bound, so that the conductive effect is improved; the surface of the graphene film is smooth, and the thickness of the graphene is uniform, so that the performance of the graphene film is improved, and the conductive film with good performance is obtained; in addition, the graphene is prepared at room temperature by the method of the present application, with no need for high temperature, low requirement for equipment, and no requirement for a catalyst layer, which enables the graphene to be suitable for batch use.

### BRIEF DESCRIPTION OF DRAWINGS

The accompanying drawings, which are included to provide a further understanding of embodiments of the present application and constitute a part of the specification, illustrate embodiments of the application and, together with the text description, explain the principles of the application. Obviously, the drawings in the following description are merely some embodiments of the present application, and those skilled in the art can obtain other drawings according to the drawings without any inventive labor. In the drawings:

FIG. 1 is a flowchart of a manufacturing method for a graphene film according to an embodiment of the present application;

FIG. 2 is a flowchart of a specific manufacturing method for a graphene film according to an embodiment of the present application;

FIG. 3 is a schematic diagram of an electrochemical deposition process according to an embodiment of the present application;

FIG. 4 is a schematic diagram of a pulse waveform according to an embodiment of the present application;

FIG. 5 is a flowchart of a manufacturing, method for a graphene material according to another embodiment of the present application; and

FIG. 6 is a schematic diagram illustrating a connection between a transparent conductive layer and an active switch in a display panel according to another embodiment of the present application.

### DETAILED DESCRIPTION OF EMBODIMENTS

It should be understood that the terminology, specific structural and functional details disclosed are merely exemplary for the purpose of describing specific embodiments. However, the present application may be embodied in many alternative forms and should not be construed as being limited to the embodiments set forth herein.

In the description of the present application, the terms “first” and “second” are only for the purpose of description and cannot be construed to indicate relative importance or imply an indication of the number of technical features indicated. Therefore, unless otherwise stated, a feature defined as “first” and “second” may explicitly or implicitly include one or more of the features; “multiple” means two or more. The tem “include” and any variations thereof are intended to be inclusive in a non-closed manner, that is, the presence or addition of one or more other features, integers, steps, operations, units, components and/or combinations thereof may be possible.

In addition, the terms “center”, “transverse”, “up”, “down”, “left”, “right”, “vertical”, “horizontal”, “top”, “bottom”. “inner”, “outer” and the like for indicating an orientation or positional relationship are based on the description of the orientation or relative positional relationship shown in the accompanying drawings, and are only simplified description facilitating description of the application, and are not intended to indicate that the device or element referred to must have a particular orientation, be configured and operated in a particular orientation, and therefore cannot be construed as limiting the present application.

In addition, unless expressly specified and defined otherwise, the terms “mount”, “attach” and “connect” are to be understood broadly, for example, it can be a fixed connection, a detachable connection, or an integral connection; it can be an either mechanical connection or an electrical connection; it can be a direct connection or an indirect connection through an intermediate medium, or an internal connection between two elements. For those skilled in the art, the specific meaning of the above terms in this application can be understood according to the specific circumstances.

The present application will be further described below with reference to the accompanying drawings and optional embodiments.

A graphene film is a transparent conductive film with good conductive effect, that can be used as a conductive film in a thin film transistor to replace an original 11.0 conductive film in the thin film transistor; due to characteristic limitations of ITO, for example: (1) the ITO exhibits uneven light absorption in the visible light range and is not suitable for full-band operation; (2) the has low conductivity, which is likely to result in poor product effects, and the thickness of a transparent electrode layer is thick, so that the development trend of thinner and lighter touch control markets is not met; (3) the ITO material is very brittle and can be easily damaged during industrial preparation, resulting economic losses and waste of resources, so that the ITO is not suitable for the development trend of flexible touch screens in the future; (4) the ITO has unstable chemical properties and poor heat dissipation, which greatly, limits its application to high power devices; and (5) the IOT material is toxic, which is not good for environmental protection, meanwhile, indium is a rare element with low reserves and increasing price, which is a waste of resources, the ITO is not the development trend of green energy saving and environmental protection and market economy in the future.

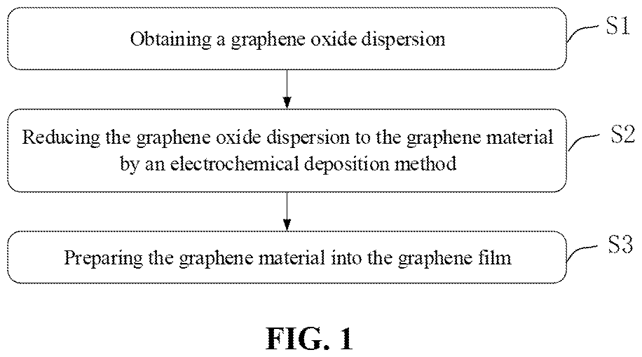

An embodiment of the present application discloses a manufacturing method for a graphene film, as shown in FIG. 1, including steps of:
S1: obtaining a graphene oxide dispersion;
S2: reducing the graphene oxide dispersion to a graphene material by an electrochemical deposition method; and
S3: preparing the graphene material into the graphene film.

Graphene is prepared by reduction through an electrochemical deposition method, and electrochemical parameters are controlled in the reduction process, so that the particle size of the prepared graphene is small, the graphene film prepared from the graphene with small particle size has high density, and graphene particles are tightly bound, so that the conductive effect is improved; the surface of the graphene film is smooth, and the thickness of the graphene is uniform, so that the performance of the graphene film is improved, and the conductive film with good performance is obtained; in addition, the graphene is prepared at room temperature by the method of the present application, with no need for high temperature, low requirement for equipment, and no requirement for a catalyst layer, which enables the graphene to be suitable for batch use. The graphene film manufactured by the manufacturing method for a graphene film in the present application has excellent conductivity, transparency and other properties, and is suitable for use in panels of all sizes; in addition, as no waste and scrap is generated in all steps, the process of manufacturing the graphene film by the manufacturing method for a graphene film in the present application is green and pollution-free.

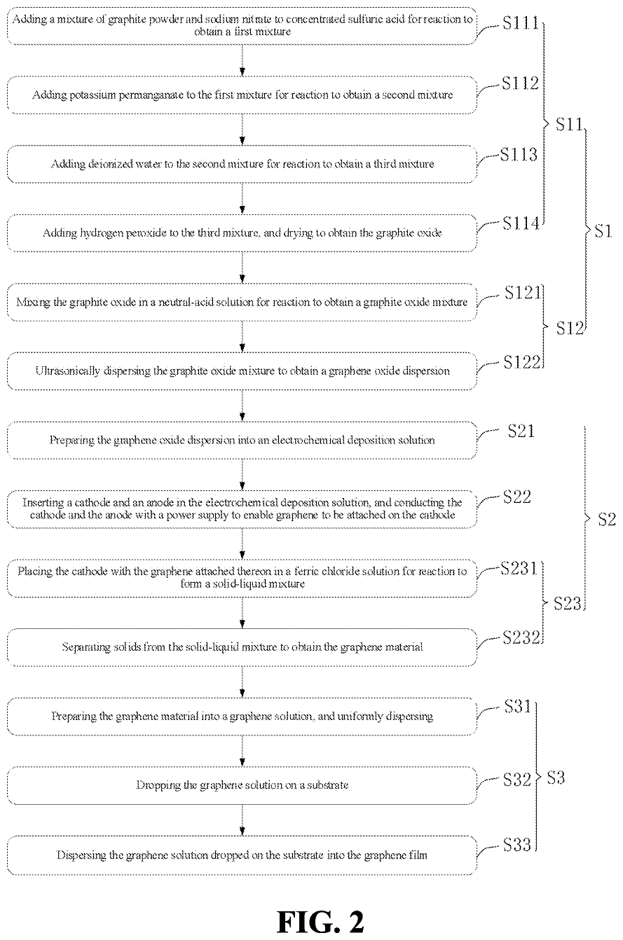

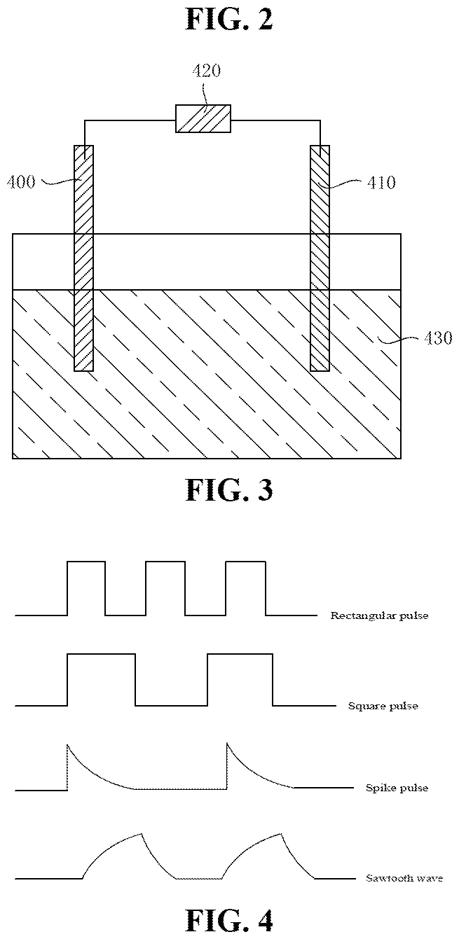

Specifically, FIG. 2 shows a flowchart of a specific manufacturing method for a graphene film, and the step S1 includes sub-steps of:
S11: preparing graphite as a raw material into a graphite oxide; and
S12: preparing the graphite oxide into a graphene oxide dispersion.

In the present application, the graphene dispersion can be purchased directly or prepared. However, due to high price of the graphene dispersion, graphite oxide with lower price can be purchased and converted into a graphene oxide dispersion, which helps reduce the production cost; While the cost of the graphite raw material without treatment is lower than that of the graphite oxide, thus the use of the graphite raw material to prepare the graphene by steps can better meet the requirement of low cost.

As for how to prepare the graphite raw material into the graphite oxide, as shown in FIG. 2, the step S11 includes sub-steps of:
S111: adding a mixture of graphite powder and sodium nitrate to concentrated sulfuric acid for reaction to obtain a first mixture;
S112: adding potassium permanganate to the first mixture for reaction to obtain a second mixture;
S1131 adding deionized water to the second mixture for reaction to obtain a third mixture; and S114: adding hydrogen peroxide to the third mixture, and drying to obtain the graphite oxide.

In this solution, natural graphite is directly taken as a raw material to prepare the graphite oxide by a Hummers method, which is featured by low raw material cost and high production efficiency, and can reduce the production cost. Specifically, the step S111 can be subdivided into: placing a beaker in an ice-water bath, adding 23-30 mL of concentrated sulfuric acid, and controlling the temperature at 0-5° C.; and adding a solid mixture of 1-2 g of graphite powder and 0.2-1 g of sodium nitrate while stirring to obtain the first mixture. The step S112 can be subdivided into: adding 1-4 g of potassium permanganate in portions, controlling the reaction temperature within 20° C. (low temperature reaction), removing the water bath after the potassium permanganate is added, and then heating to about 30-50° C. (medium temperature reaction) to obtain the second mixture. The step S113 can be subdivided into: stirring the second mixture for 10-60 min, then adding 400-800 mL of deionized water slowly, and heating to 50-100° C. (high temperature reaction) for reaction for 10-60 min to obtain the third mixture. The step S114 can be subdivided into: diluting the third mixture to 100-200 mL, adding a proper amount of 30% hydrogen peroxide, stirring well, then filtering, Washing and drying to obtain the graphite oxide. In the present application, a variety of intermediate products can be prepared as needed by preparing graphite into a graphite oxide, preparing the graphite oxide into a graphite oxide dispersion, and preparing the graphite oxide dispersion into graphene, and in the process of preparing graphite into the graphene by steps, the present application can save a lot of production costs due to low price of the graphite raw material.

As for how to prepare the graphite oxide into the graphene oxide dispersion, the present application further provides specific operation steps, that is, the step S12 includes sub-steps of:
S121: mixing the graphite oxide in an acid solution for reaction to obtain a graphite oxide mixture; and
S122: ultrasonically dispersing the graphite oxide mixture to obtain a graphene oxide dispersion.

Compared with a general solution for dispersion of a graphite oxide into graphene by ultrasonic dispersion, the present application provides an acidic condition to keep the graphite oxide in an acidic environment, which can accelerate the dispersion efficiency of the graphite oxide. The acid solution in S121 can be phosphoric acid, hydrochloric acid, acetic acid or other acid solution.

As shown in FIG. 2, the step S2 includes sub-steps of:
S21: preparing the graphene oxide dispersion into an electrochemical deposition solution;
S22: inserting a cathode and an anode in the electrochemical deposition solution, and conducting the cathode and the anode with a power supply to enable graphene to be attached on the cathode: and
S23: removing the cathode to obtain the graphene material.

As shown in FIG. 3. FIG. 3 is a schematic diagram of an electrochemical deposition apparatus. Electrochemical Deposition (ECD) is a technique in which positive and negative ions migrate in an electrolyte solution when current passes through the electrolyte solution under the action of an applied electric field and an oxidation-reduction reaction gaining or losing electrons occurs on an electrode to form a coating. Where the reduction of metal ions produced at the cathode to obtain a metal coating is called electroplating; oxidation of an anodic metal occurs at the anode to form a suitable oxide film, which is called electrochemical oxidation of metal. The electrochemical deposition apparatus includes a container containing an electrochemical deposition solution 430, a cathode 410 and an anode 400 inserted into the electrochemical deposition solution 430, where a reduction reaction occurs at the cathode 410, an oxidation reaction occurs at the anode 400, and the cathode 410 is in communication with the anode 400 through a power supply 420. In the present application, the graphene oxide dispersion is reduced to the graphene material by an electrochemical deposition method. Compared with the preparation of graphene by other chemical reduction methods, the electrochemical deposition method is more efficient in reducing to graphene. In addition, the electrochemical deposition method can improve the production rate of the graphene by increasing the power of the power supply 420, improve the production rate of the graphene by increasing the surface area of the cathode 410 in the electrochemical deposition solution 430, and improve the production efficiency of the graphene by increasing the concentration of the electrochemical deposition solution 430. Based on this, the electrochemical deposition method can improve the production efficiency of the graphene by controlling a plurality of conditions to produce a more efficient graphene film.

Specifically, in the step S21, the electrochemical deposition solution consists of the graphene oxide dispersion and a pH regulator which is citric acid and sodium citrate with a pH value of 2 to 6. In the step S22, the cathode 410 is made of nickel, and the anode 400 is made of platinum or titanium. Nickel is used as a cathode in the reaction, and has a second effect of being used as a catalyst, so that the production of the catalytic graphene is accelerated, and the reduction efficiency of the graphene is improved. The anode is made of platinum or titanium, because platinum and titanium are inert metals that do not lose or gain electrons easily, do not react with the electrochemical deposition solution, and do not affect the concentration of the graphene oxide in the electrochemical deposition solution, so that the electrochemical decomposition solution reacts only with the cathode, improving the production efficiency of the graphene.

In addition, the power supply 420 in the step S22 is a pulse power supply. Electrochemical deposition is divided into direct current electrodeposition and pulse electrodeposition. Pulse electrodeposition is a process in which deposited ions consumed at a cathode-solution interface can be replenished within a pulse interval after a pulse current is provided by the power supply 420, so that a higher peak current density can be adopted, and the resulting grain size is smaller than that obtained by direct current electrodeposition. In addition, due to the existence of pulse intervals when the pulse current is applied, growing crystals are hindered, the epitaxial growth is reduced, and the growth trend is changed, so that thick crystals are not easy to form, and the deposition process can be adjusted by adjusting the pulse current density, pulse on time and pulse off time. Therefore, the graphene is prepared by pulse electrodeposition in the present application, that is, a pulse power supply is adopted, so that the graphene with small particle size can be produced, the density of the graphene is increased, and the formed graphene film has the advantages of smooth surface, uniform interior and good performance. In addition, there is a problem in traditional electrochemical reduction that oxygen-containing functional groups are easy to remain on the surface of the formed graphene, which makes the graphene material lack purity. While the present application controls and regulates the degree of reduction by controlling parameters such as duty and frequency of the pulse voltage to make the particle size of the graphene smaller and more tightly bound, so that oxygen-containing functional groups are less likely to remain on the surface of the graphene. After tests, the inventor found that when the frequency of the pulse voltage provided by the pulse power supply is set at 10000 Hz to 50000 Hz and the duty is set at 10% to 60%, it is less likely that oxygen-containing functional groups remain on the surface of the formed graphene.

Parameters adopted in the present application to prepare the graphene material by pulse electrochemical reduction are shown in Table 1, and the graphene material with sufficiently small grain size can be prepared based on the parameters; where pulse waveforms are divided into rectangular waves, sawtooth waves and triangular waves. FIG. 4 shows a schematic diagram of several pulse waveforms, and any of the waveforms can meet the requirements of the present application.

TABLE 1
Parameters of pulse electrochemical deposition

| Current | Voltage | Frequency | Duty | Pulse | |
|---|---|---|---|---|---|
| (A) | (V) | (Hz) | (%) | width (s) | Waveform |
| 0.1-2.0 | 1-30 | 10000- | 10-60 | 0.01-1 | Rectangular waves, |
| | | 500000 | | | sawtooth waves, |
| | | | | | triangular waves |
| | | | | | and the like |

After the graphene is attached on the cathode 410 by an electrochemical deposition method, the graphene is hard to be separated from the cathode 410, so that the graphene cannot be adopted directly, and other operations are required to obtain a pure graphene material for use. The starting point of obtaining a pure graphene material in the present application is to chemically remove the cathode 410 with the graphene attached thereon, leaving only the graphene, so that no graphene is wasted and all graphene is left. Specifically, the step S23 includes sub-steps of:
S231: placing the cathode with the graphene attached thereon in a ferric chloride solution for reaction to form a solid-liquid mixture; and
S232: separating solids from the solid-liquid mixture to obtain the graphene material.

Specifically, the cathode 410 with the graphene attached thereon is taken out of the electrochemical deposition solution, rinsed to remove other substances thereon, dried, and then placed into a ferric chloride (FeCl3) solution, where nickel reacts with ferric chloride to produce ferrous chloride and nickel chloride, leaving only the solid graphene which can be put into the next process after being filtered, cleaned and dried. Acetic acid can also be added to ferric chloride to promote the reaction with nickel to form nickel acetate which is soluble in water.

The step S3 includes sub-steps of:
S31: preparing the graphene material into a graphene solution, and uniformly dispersing;
S32: dropping the graphene solution on a substrate; and
S33: dispersing the graphene solution dropped on the substrate into the graphene film.

In the present application, the graphene film is manufactured by a spin-coating method.

Compared with other film forming methods, the spin-coating method spreads the graphene by centrifugal force on the basis of high speed rotation, so that the formed graphene is more uniform. Specifically, the graphene is dispersed in a dispersion which is ethanol or cyclopentanone to prepare a graphene solution with a concentration of 1-5% (ethanol, methanol, isopropanol or other solution added with a surfactant such as sodium dodecyl sulfate, sodium dodecyl benzene sulfonate and polyvinyl alcohol) and uniformly dispersed, and then the dispersion is dropped on a substrate and dispersed into a film by using a spin coating machine.

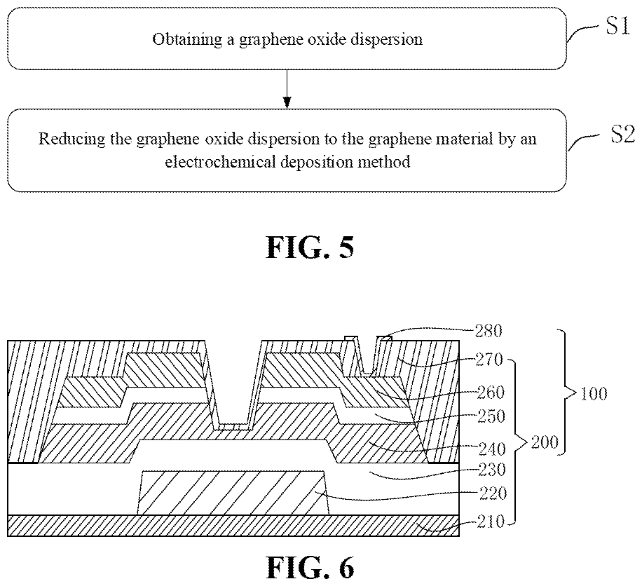

As another embodiment of the present application, a manufacturing method for a graphene material is further disclosed. FIG. 5 shows a manufacturing method for a graphene material, including steps of:
S1: obtaining a graphene oxide dispersion and
S2: reducing the graphene oxide dispersion to the graphene material by an electrochemical deposition method.

The graphene material has excellent optical, electrical and mechanical properties, is promising in applications in fileds of sensors, transistors, flexible display, new energy, hydrogen storage, composites, aerospace, biology and the like, and is considered to be a revolutionary material in the future. In the technical field of display panels, the graphene material can replace the traditional ITO material as transparent conductive layers, and can be used as pixel electrodes or common electrodes of display panels to improve the performance of the display panels. As another embodiment of the present application, a display panel is further disclosed, where the display panel 100 includes a graphene film 280 prepared by the manufacturing method for a graphene film as a transparent conductive layer. It should be noted that the transparent conductive layer can be used as a pixel electrode or a common electrode of the display panel.

FIG. 6 shows a schematic diagram of a connection between a transparent conductive layer used as a pixel electrode and an active switch in a display panel, where the display panel further includes an active switch 200, the active switch 200 includes a substrate 210, a gate metal layer 220, a gate insulating layer 230, an active layer 240, an ohmic contact layer 250, a source/drain metal layer 260 and a passivation layer 270 which are sequentially stacked, and the pixel electrode made of the graphene film 280 is connected to the source/drain metal layer 260 through a via hole of the passivation layer 270. The graphene film 280 manufactured by the manufacturing method for a graphene film as described above has the characteristics of good conductivity, high density, uniform thickness and good transparency, so that the display effect of the display panel is better.

It should be noted that, the limitation of the steps involved in this solution, without affecting the implementation of the specific solution, is not determined to limit the sequence of steps, and the previous steps may be executed first, later, or even simultaneously, and shall be deemed to fall within scope of the present application as long as the solution can be implemented.

The technical solution of the present application can be widely applied to a variety of electronic devices such as display panels, touch screens or solar cells. The above content is a further detailed description of the present application in conjunction with specific, optional embodiments, and it is not to be construed that specific embodiments of the present application are limited to these descriptions. For those of ordinary skill in the art to Which this application belongs, a number of simple derivations or substitutions may be made without departing from the spirit of this application, all of which shall be deemed to tall within the scope of this application.

What is claimed is:

1. A manufacturing, method for a graphene film, comprising steps of:
obtaining a graphene oxide dispersion;
reducing the graphene oxide dispersion to a graphene material by an electrochemical deposition method; and
preparing the graphene material into the graphene film.

2. The manufacturing method for the graphene film according to claim 1, wherein the step of reducing the graphene oxide dispersion to a graphene material by an electrochemical deposition method comprises sub-steps of:
preparing the graphene oxide dispersion into an electrochemical deposition solution;
inserting a cathode and an anode in the electrochemical deposition solution, and conducting the cathode and the anode with a power supply to enable graphene to be attached on the cathode; and
removing the cathode to obtain the graphene material.

3. The manufacturing method for the graphene film according to claim 2, wherein the cathode is made of nickel, and the anode is made of platinum or titanium.

4. The manufacturing method for the graphene film according to claim 2, wherein the power supply is a pulse power supply that provides pulse voltage at a frequency of 10000 HZ to 50000 HZ, with a duty of 10% to 60%.

5. The manufacturing method for the graphene film according to claim 2, wherein the step of removing the cathode to obtain the graphene material comprises sub-steps of:
placing the cathode with the graphene attached thereon in a ferric chloride solution for reaction to form a solid-liquid mixture;
separating solids from the solid-liquid mixture to obtain the graphene material.

6. The manufacturing method for the graphene film according to claim 2, wherein the electrochemical deposition solution consists of the graphene oxide dispersion and a pH regulator, which is citric acid and sodium citrate with a pH value of 2 to 6.

7. The manufacturing method for the graphene film according to claim 1, wherein the step of obtaining a graphene oxide dispersion comprises sub-steps of:
preparing graphite as a raw material into a graphite oxide; and
preparing the graphite oxide into the graphene oxide dispersion.

8. The manufacturing method for the graphene film according to claim 7, wherein the step of preparing the graphite oxide into the graphene oxide dispersion comprises sub-steps of:
mixing the graphite oxide in an acid solution for reaction to obtain a graphite oxide mixture; and
ultrasonically dispersing the graphite oxide mixture to obtain a graphene oxide dispersion.

9. The manufacturing method for the graphene film according to claim 7, wherein the step of preparing graphite as a raw material into a graphite oxide comprises sub-steps of:
adding a mixture of graphite powder and sodium nitrate to concentrated sulfuric acid for reaction to obtain a first mixture;
adding potassium permanganate to the first mixture for reaction to obtain a second mixture;
adding deionized water to the second mixture for reaction to obtain a third mixture; and
adding hydrogen peroxide to the third mixture, and drying to obtain the graphite oxide.

10. The manufacturing method for the graphene film according to claim 1, wherein the step of preparing the graphene material into the graphene film comprises sub-steps of:
preparing the graphene material into a graphene solution, and uniformly dispersing;
dropping the graphene solution on a substrate; and
dispersing the graphene solution dropped on the substrate into the graphene film.

11. The manufacturing method for the graphene film according to claim 9, wherein the step of preparing the first mixture comprises placing a beaker in an ice-water bath, adding 23-30 mL of concentrated sulfuric acid, and controlling the temperature at 0-5° C.; and adding a solid mixture of 1-2 g of graphite powder and 0.2-1 g of sodium nitrate while stirring to obtain the first mixture.

12. The manufacturing method for the graphene film according to claim 9, wherein the step of preparing the second mixture comprises adding 1-4 g of potassium permanganate in portions, controlling the reaction temperature within 20° C., removing the water bath after adding potassium permanganate, and then heating to 30-50° C. to obtain the second mixture.

13. The manufacturing method for the graphene film according to claim 12, wherein the step of preparing the third mixture comprises stirring the second mixture for 10-60 min, then adding 400-800 mL of deionized water slowly, and heating to 50-100° C. for reaction for 10-60 min to obtain the third mixture.

14. The manufacturing method for the graphene film according to claim 13, wherein the step of preparing the graphite oxide comprises diluting the third mixture to 100-200 mL, adding a proper amount of 30% hydrogen peroxide, stirring well, then filtering, washing awl drying to obtain the graphite oxide.

15. The manufacturing method for the graphene film according to claim 8, wherein the acid solution is phosphoric acid, hydrochloric acid, acetic acid or other acid solution.

16. The manufacturing method for the graphene film according to claim 4, wherein pulse waveforms of the pulse power supply are divided into rectangular waves, sawtooth waves and triangular waves.

17. A display panel, comprising a transparent conductive layer which is a graphene film prepared by the manufacturing method for the graphene film according to claim 1 and used as pixel electrodes or common electrodes of display panels.
